(19) United States
(12) Patent Application Publication
(10) Pub. No.: US 2008/0090014 A1
(43) Pub. Date: Apr. 17, 2008

(54) Organic light emitting display having light absorbing layer and method for manufacturing same

(75) Inventor: Shuo-Ting Yan, Miao-Li (TW)

Correspondence Address: WEI TE CHUNG;FOXCONN INTERNATIONAL, INC., 1650 MEMOREX DRIVE, SANTA CLARA, CA, 95050, US

(73) Assignee: INNOLUX DISPLAY CORP.

(21) Appl. No.: 11/974,050

(22) Filed: Oct. 11, 2007

(30) Foreign Application Priority Data
Oct. 11, 2006 (TW) 95137304

(51) Int. Cl. H01L 27/28; B05D 1/36

(52) U.S. Cl. 427/404; 313/504

(57) ABSTRACT

An exemplary organic light emitting display (200) includes a substrate (20), a first electrode layer (22), an organic layer (23), and a second electrode layer (21). The first electrode layer is disposed at the substrate. The organic layer is disposed at the first electrode layer. The second electrode layer includes a photic layer (210) disposed on the organic layer, an absorbing layer (211) disposed on the photic layer, and a metal layer (212) disposed on the absorbing layer. The absorbing layer is configured to absorb light beams passing through the photic layer. A method for manufacturing the organic light emitting display is also provided.

### FIELD OF THE INVENTION

The present invention relates to organic light emitting displays (OLEDs), and more particularly to an OLED having a light absorbing layer for absorbing ambient light beams. The present invention also relates to a method for manufacturing such OLED.

### GENERAL BACKGROUND

OLEDs are self-luminous devices driven by low-level direct current (DC) voltages. Unlike with a typical liquid crystal display (LCD), an OLED does not require a backlight module to provide light beams needed for displaying of images. Thus, OLEDs have lower power consumption. Moreover, OLEDs have other advantages, such as higher color saturation and faster response times. As a result, OLEDs are being used more and more widely.

FIG. 5 is a schematic side view of a conventional OLED. The OLED 100 includes a substrate 10, an anode layer 12, an organic layer 13, and a cathode layer 11, stacked in that order from bottom to top. The organic layer 13, the anode layer 12, and the substrate 10 are all made of transparent material, and the cathode layer 11 is made of metal.

The organic layer 13 has a multi-layer structure. The multi-layer structure includes an electron injection layer (EIL) 133, an electron transport layer (ETL) 131, an emitting layer (EML) 130, a hole transport layer (HTL) 132, and a hole injection layer (HIL) 134, which are stacked between the cathode layer 11 and the anode layer 12 in that order from top to bottom. The EIL 133 is configured to reduce the potential barrier between the cathode layer 11 and the ETL 131. The HIL 134 is configured to reduce the potential barrier between the anode layer 12 and the HTL 131.

In operation, a DC voltage is applied to the anode layer 12 and the cathode layer 11, so that a plurality of electrons are provided by the cathode layer 11 and a plurality of holes are provided by the anode layer 12, respectively. The electrons emit from the cathode layer 11, pass through the EIL 133 and the ETL 131, and then arrive at the EML 130. The holes emit from the anode layer 12, pass through the HIL 134 and the HTL 132, and then also arrive at the EML 130. In the EML 130, recombination occurs between each of the electron-hole pairs. During the recombination, the electron transits from an energy band having a higher energy level to an energy band having a lower energy level. Thus, the energy of the recombined electrons is reduced, and energy is released via generation of photons. Accordingly, a plurality of emitting light beams are generated in the EML 130. Most of the emitting light beams 140 transmit down through the HTL 132, the HIL 134, the anode layer 12, and the substrate 10 sequentially, and then emit from a bottom surface of the substrate 10. The rest of the emitting light beams 141 transmit up, and are reflected by the cathode layer 11 and become reflected light beams 142. The reflected light beams 142 then transmit through the organic layer 13, the anode layer 12, and the substrate 10 sequentially, and also emit from the bottom surface of the substrate 10. Thereby, the emitting light beams 140, together with the reflected light beams 142, enable the OLED 100 to display images.

However, the optical paths of the emitting light beams 140 are different with those of the reflected light beams 142. These optical path differences are liable to cause generation of phase differences between the emitting light beams 140 and the reflected light beams 142, which in turn may induce an optical interference phenomenon and reduce the display quality of the OLED 100. Moreover, if the OLED 100 is used in a bright ambient environment, ambient light beams 150 enter the OLED 100, and are reflected by the cathode layer 11 to become reflected light beams 151. The reflected light beams 151 then transmit through the organic layer 13, the anode layer 12, and the substrate 10 sequentially, and emit from the bottom surface of the substrate 10. When the OLED 100 displays a black or dark image, the reflected light beams 151 may increase the brightness of the black or dark image, so that the contrast ratio of the OLED 100 is reduced.

It is desired to provide an OLED and a method for manufacturing the OLED, which can overcome the above-described deficiencies.

### SUMMARY

In one aspect, an organic light emitting display includes a substrate, a first electrode layer, an organic layer, and a second electrode layer, the first electrode layer in disposed at the substrate, the organic layer is disposed at the first electrode layer, the second electrode layer a photic layer disposed on the organic layer, an absorbing layer disposed on the photic layer, and a metal layer disposed on the absorbing layer, the absorbing layer is configured to absorb light beams passing through the photic layer.

In another aspect, a method for manufacturing an organic light emitting display includes: providing a substrate; forming a first electrode layer at the substrate; forming an organic layer at the first electrode layer; and forming a photic layer on the organic layer, an absorbing layer on the photic layer, and a metal layer on the absorbing layer.

Other novel features and advantages of the above-described organic light emitting display and manufacturing method thereof will become more apparent from the following detailed description when taken in conjunction with the accompanying drawings.

### BRIEF DESCRIPTION OF THE DRAWINGS

FIG. 1 is a schematic side view of an organic light emitting display according to a first exemplary embodiment of the present invention, showing essential optical paths thereof.

FIG. 2 is a flow chart of an exemplary method for manufacturing the organic light emitting display of FIG. 1.

FIG. 3 is a schematic side view of an organic light emitting display according to a second exemplary embodiment of the present invention.

FIG. 4 is a schematic side view of an organic light emitting display according to a third exemplary embodiment of the present invention.

FIG. 5 is a schematic side view of a conventional organic light emitting display, showing essential optical paths thereof.

### DETAILED DESCRIPTION OF PREFERRED EMBODIMENTS

Reference will now be made to the drawings to describe preferred and exemplary embodiments of the present invention in detail.

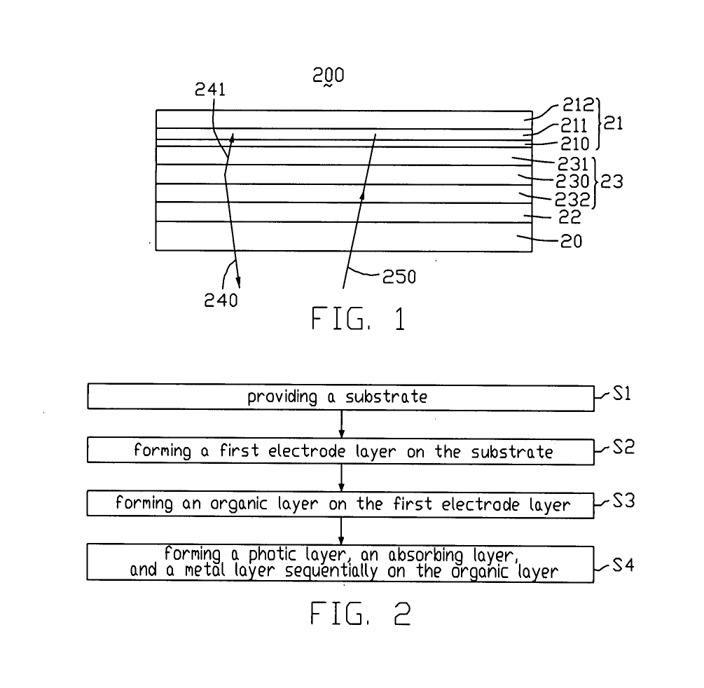

FIG. 1 is a schematic side view of an organic light emitting display (OLED) 200 according to a first exemplary embodiment of the present invention. The OLED 200 includes a substrate 20, a first electrode layer 22, an organic layer 23, and a second electrode layer 21.

The substrate 20 is transparent, and can for example be made of glass. The substrate 20 includes an upper surface (not labeled) and a bottom surface (not labeled). The bottom surface is configured to be a light emitting surface of the OLED 200. That is, images displayed by the OLED 200 are viewed at the bottom surface.

The first electrode layer 22 is configured to be an anode layer, and is made of transparent, electrically conductive material such as indium tin oxide (ITO) or indium zinc oxide (IZO). The first electrode layer 22 is disposed on the upper surface of the substrate 20. A thickness of the first electrode layer 22 is in the range from 25 nanometers (nm) to 100 nm.

The organic layer 23 has a triple-layer structure. The triple-layer structure includes a hole transport layer (HTL) 232, an emitting layer (EML) 230, and an electron transport layer (ETL) 231 stacked on the first electrode layer 22 in that sequence. An overall thickness of the organic layer 23 is in the range from 80 nm to 150 nm.

The HTL 232 is made of transparent P-type organic material having high hole mobility, such as n-propyl bromide (NPB). A highest occupied molecule orbital (HOMO) of the HTL 232 is close to that of the first electrode layer 22, so as to lower the potential barrier between the THL 232 and the first electrode layer 22. Thus, holes provided by the first electrode layer 22 can transmit to the THL 232 easily.

The EML 230 and the ETL 231 are both made of transparent N-type organic material having high electron mobility, such as aluminum-tris-quinolate (Alq₃). Fluorescent organic material is doped into the EML 230, such that the fluorescent organic material occupies about 1% to 10% by volume of the doped N-type organic material. The fluorescent organic material is doped into the EML 230 to control the optical spectrum, as well as to increase the luminous efficiency. A lowest unoccupied molecule orbital (LUMO) of each of the EML 230 and the ETL 231 is much greater than the HOMO of the HTL 232, so that the potential barrier between the EML 230 and the HTL 232 is sufficiently great. Thus, it is very difficult for electrons in the EML 230 to transmit into the HTL 232.

The second electrode layer 21 is configured to be a cathode layer, and has a triple-layer structure. The triple-layer structure includes a photic layer 210, an absorbing layer 211, and a metal layer 212 stacked on the ETL 231 in that sequence.

The photic layer 210 is made of metal or alloy having a low work function, so as to reduce the potential barrier between the organic layer 23 and the second electrode layer 21. The photic layer 210 is a thin electrically conductive film with a thickness less than the skin depth of visible light. The skin depth is defined as a depth at which the amplitude of the electromagnetic field provided by visible light beams drops to 1/e of the source amplitude. The skin depth depends on the frequency of light beams, and on the magnetic permeability and conductivity of the photic layer 210. Thus, visible light beams can transmit through the photic layer 210. Typically, the thickness of the photic layer 210 is in the range from 2 nm to 12 nm. A material of the photic layer 210 can be one of calcium (Ca), magnesium (Mg), and lithium fluoride (LiF).

The absorbing layer 211 is configured to absorb light beams passing through the photic layer 210. The absorbing layer 211 is made of electrically conductive material capable of absorbing visible light beams; for example, graphite. A thickness of the absorbing layer 211 is in the range from 5 nm to 10 nm.

The metal layer 212 is mainly configured to be a conductive electrode, as well as to protect the absorbing layer 211 and the photic layer 210 of the second electrode layer 21. The metal layer 212 is made of metal having high electrical conductivity, such as silver (Ag) or aluminum (Al). A thickness of the metal layer 212 is in the range from 100 nm to 150 nm.

In operation, a direct current voltage is applied to the first electrode layer 22 and the metal layer 212 for driving the OLED 200 to display images. Due to the direct current voltage, a plurality of holes are provided by the first electrode layer 22, and a plurality of electrons are provided by the second electrode layer 21, respectively. The holes emit from the first electrode layer 22, pass through the HTL 232, and then arrive at the EML 230. Simultaneously, the electrons emit from the second electrode layer 21, pass through the ETL 231, and then also arrive at the EML 230. The electrons are obstructed from transmitting into the HTL 232 because of the potential barrier caused by the difference between the HOMO of the HTL 232 and the LUMO of the EML 230. Therefore, almost all of the electrons stay in the EML 230.

In the EML 230, recombination is induced between each of the electron-hole pairs. During the recombination, the electron transits from an energy band having a higher energy level to an energy band having a lower energy level. Thus, the energy of the recombined electrons is reduced, and energy is released via generation of photons. Due to the optical spectrum control function of the fluorescent organic material in the EML 230, emitting light beams having a corresponding frequency are thereby generated.

Most of the emitting light beams 240 transmit down through the HTL 232, the first electrode layer 22, and the substrate 20 sequentially, and then emit from the bottom surface of the substrate 20. Thereby, the OLED 200 is able to display images. The rest of the emitting light beams 241 transmit up, pass through the ETL 231 and the photic layer 210, and then are absorbed by the absorbing layer 211. Further, ambient light beams 250 enter the OLED 200 via the bottom surface, pass through the substrate 20, the first electrode layer 22, the organic layer 23, and the photic layer 210 sequentially, and then are also absorbed by the absorbing layer 211.

As described above, the light beams 241 and 250 that transmit to the second electrode layer 21 are absorbed by the absorbing layer 211 therein. Therefore, no reflected light beams emit from the bottom surface of the substrate 20 of the OLED 200. Thus, any interference phenomenon that would otherwise exist is substantially reduced or even eliminated, because the light beams 241, 250 are not able to reflect back down and interfere with the emitting light beams 240. Accordingly, the display quality of the OLED 200 can be improved. Moreover, when the OLED 200 displays a black or dark image, because there are substantially no reflected light beams, the brightness of the OLED 200 can be maintained at a suitable lower level, so that the contrast ratio of the OLED 200 is improved.

FIG. 2 is a flow chart of an exemplary method for manufacturing the OLED 200. The method includes the following steps: S1, providing a substrate; S2, forming a first electrode layer on the substrate; S3, forming an organic layer on the first electrode layer; and S4, forming a photic layer, an absorbing layer, and a metal layer sequentially on the organic layer.

In step S1, a substrate 20 is provided. The substrate 20 is transparent, and is typically made of glass.

In step S2, a first electrode layer 22 is deposited on the substrate 20 via physical vapor deposition (PVD). The material of the first electrode layer 22 is transparent, electrically conductive material such as ITO or IZO. A thickness of the first electrode layer 22 is controlled to be in the range from 25 nm to 100 nm, by controlling the deposition time.

Step S3 includes the following steps: forming a hole transport layer (HTL) 232 on the first electrode layer 22; forming an emitting layer (EML) 230 on the HTL 232; and forming an electron transport layer (ETL) 231 on the EML 230.

In detail, firstly, the HTL 232 is deposited on the first electrode layer 22. The HTL 232 is made of transparent P-type organic material having high hole mobility, such as NPB.

Secondly, a transparent N-type organic layer having high electron mobility is deposited on the HTL 232, and then fluorescent organic material is doped into the N-type organic layer. The material of the N-type organic layer can be Alq₃, and the fluorescent organic material can occupy about 1% to 10% by volume of the doped N-type organic material. After that, the EML 230 is deposited on the HTL 232.

Thirdly, the ETL 231 is deposited on the EML 230, so that the organic layer 23 including the HTL 232, the EML 230, and the ETL 231 is formed on the first electrode layer 22. The ETL 231 is a transparent N-type organic material such as Alq₃. An overall thickness of the organic layer 23 is controlled to be in the range from 80 nm to 150 nm. The HTL 232, the EML 230, and the ETL 231 can each be formed by a selected one of the following methods: PVD, spin coating, and printing.

Step S4 includes the following steps: forming a photic layer 210 on the ETL 231; forming an absorbing layer 211 on the photic layer 210; and forming a metal layer 212 on the absorbing layer 211.

In detail, firstly, the photic layer 210 is deposited on the ETL 231. The photic layer 210 is made of material having a low work function, such as a selected one of Ca, Mg, and LiF. A thickness of the photic layer 210 is controlled to be in the range from 2 nm to 12 nm.

Secondly, the absorbing layer 211 capable of absorbing visible light beams is deposited on the photic layer 210. A thickness of the absorbing layer 211 is controlled to be in the range from 5 nm to 10 nm. The material of the absorbing layer 211 can be graphite.

Thirdly, the metal layer 212 having a thickness in the range from 100 nm to 150 nm is deposited on the absorbing layer 211. The material of the metal layer 212 can be Ag or Al. After that, the second electrode layer 21 is deposited on the organic layer 23. The photic layer 210, the absorbing layer 211, and the metal layer 212 can all be formed via PVD.

Furthermore, a passivation layer can be formed on the second electrode layer 21, to protect the OLED 200 from being oxidized.

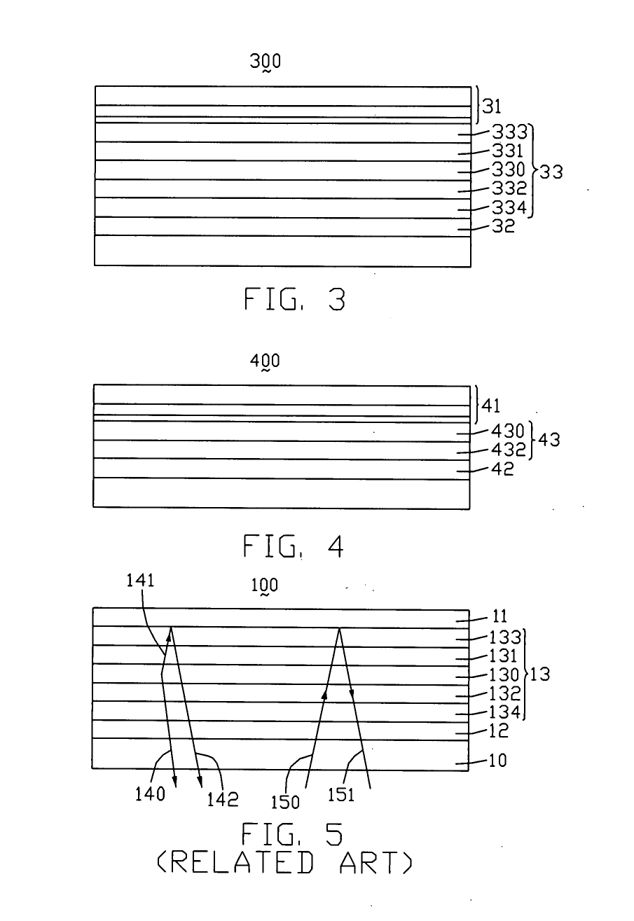

FIG. 3 is a schematic side view of an OLED 300 according to a second exemplary embodiment of the present invention. The OLED 300 is similar to the above-described OLED 200. However, the OLED 300 includes an organic layer 33 between a first electrode layer 32 and a second electrode layer 31. The organic layer 33 includes a hole injection layer (HIL) 334, a hole transport layer (HTL) 332, an emitting layer (EML) 330, an electron transport layer (ETL) 331, and an electron injection layer (EIL) 333, stacked on the first electrode layer 32 in that sequence. The HIL 334 and the EIL 333 are each made of transparent material having low work function. The HIL 334 is configured to reduce the potential barrier between the organic layer 33 and the first electrode layer 32. The EIL 333 is configured to reduce the potential barrier between the organic layer 33 and the second electrode layer 31.

FIG. 4 is a schematic side view of an OLED 400 according to a third exemplary embodiment of the present invention. The OLED 400 is similar to the above-described OLED 200. However, the OLED 400 includes an organic layer 43 between a first electrode layer 42 and a second electrode layer 41. The organic layer 43 includes a hole transport layer (HTL) 432 and an emitting layer (EML) 430 stacked on the first electrode layer 42 in that sequence. The HTL 432 is made of a P-type organic material having high hole mobility, such as poly-ethylene-dioxy-thiophene: poly-styrenesulfonate (PEDOT: PSS). The EML 430 is made of an N-type organic material having high electron mobility, such as poly-methoxy-ethylhexyloxy-phenylenevinylene (MEH-PPV).

It is to be understood, however, that even though numerous characteristics and advantages of preferred and exemplary embodiments have been set out in the foregoing description, together with details of the structures and functions of the embodiments, the disclosure is illustrative only; and that changes may be made in detail within the principles of present invention to the full extent indicated by the broad general meaning of the terms in which the appended claims are expressed.

What is claimed is:

1. An organic light emitting display, comprising:
a substrate;
a first electrode layer disposed on the substrate;
an organic layer disposed on the first electrode layer; and
a second electrode layer comprising a photic layer disposed on the organic layer, an absorbing layer disposed on the photic layer, and a metal layer disposed on the absorbing layer;
wherein the absorbing layer is configured to absorb light beams passing through the photic layer.

2. The organic light emitting display as claimed in claim 1, wherein a thickness of the photic layer is less than the skin depth of visible light.

3. The organic light emitting display as claimed in claim 2, wherein the thickness of the photic layer is in the range from 2 nm to 12 nm.

4. The organic light emitting display as claimed in claim 3, wherein the photic layer comprises at least one material selected from the group consisting of calcium, magnesium, and lithium fluoride.

5. The organic light emitting display as claimed in claim 1, wherein the absorbing layer is an electrically conductive layer.

6. The organic light emitting display as claimed in claim 5, wherein the absorbing layer comprises graphite.

7. The organic light emitting display as claimed in claim 6, wherein a thickness of the absorbing layer is in the range from 5 nm to 10 nm.

8. The organic light emitting display as claimed in claim 1, wherein a thickness of the metal layer is in the range from 100 nm to 150 nm.

9. The organic light emitting display as claimed in claim 1, wherein the metal layer comprises at least one of aluminum and silver.

10. The organic light emitting display as claimed in claim 1, wherein the organic layer comprises a hole transport layer, an emitting layer, and an electron transport layer disposed in that sequence between the first electrode layer and the second electrode layer.

11. The organic light emitting display as claimed in claim 10, wherein the hole transport layer comprises n-propyl bromide, the emitting layer and the electron transport layer both comprise aluminum-tris-quinolate, and fluorescent organic material is doped in the emitting layer.

12. The organic light emitting display as claimed in claim 11, wherein the organic layer further comprises a hole injection layer and an electron injection layer, the hole injection layer is disposed between the hole transport layer and the first electrode layer, and the electron injection layer is disposed between the electron transport layer and the second electrode layer.

13. The organic light emitting display as claimed in claim 1, wherein the organic layer comprises a hole transport layer and an emitting layer disposed in that sequence between the first electrode layer and the second electrode layer, the hole transport layer comprises poly-ethylene-dioxy-thiophene: poly-styrenesulfonate (PEDOT: DSS), and the emitting layer comprises poly-methoxy-ethylhexyloxy-phenylenevinylene (MEH-PPV).

14. A method for manufacturing an organic light emitting display, the method comprising:
providing a substrate;
forming a first electrode layer on the substrate;
forming an organic layer on the first electrode layer; and
forming a photic layer on the organic layer, an absorbing layer on the photic layer, and a metal layer on the absorbing layer.

15. The method for manufacturing an organic light emitting display as claimed in claim 14, wherein forming an organic layer on the first electrode layer comprises forming a hole transport layer on the first electrode layer, forming an emitting layer on the hole transport layer, and forming an electron transport layer on the emitting layer.

16. The method for manufacturing an organic light emitting display as claimed in claim 15, wherein forming an emitting layer on the hole transport layer comprises forming an N-type organic layer on the hole transport layer, and doping fluorescent organic material into the N-type organic layer.

17. The method for manufacturing an organic light emitting display as claimed in claim 14, wherein a thickness of the photic layer is in the range from 2 nm to 12 nm.

18. The method for manufacturing an organic light emitting display as claimed in claim 14, wherein the absorbing layer comprises graphite.

19. The method for manufacturing an organic light emitting display as claimed in claim 14, wherein a thickness of the absorbing layer is in the range from 5 nm to 10 nm.
